(19) United States
(12) Patent Application Publication
(10) Pub. No.: US 2026/0247523 A1
(43) Pub. Date: Aug. 20, 2026

(54) HIGH-SPEED TRANSMISSION BOARD WIRING STRUCTURE

(71) Applicant: Astemo, Ltd., Chiyoda-ku, Tokyo (JP)

(72) Inventors: Naomi SHIGA, Hitachinaka-shi, Ibaraki (JP); Takayuki OTA, Hitachinaka-shi, Ibaraki (JP); Katsuya OYAMA, Hitachinaka-shi, Ibaraki (JP)

(73) Assignee: Astemo, Ltd., Chiyoda-ku, Tokyo (JP)

(21) Appl. No.: 19/469,411

(22) PCT Filed: May 22, 2023
(86) PCT No.: PCT/JP2023/018954

§ 371 Date: Sep. 26, 2025

(51) Int. Cl. H05K 1/02

(52) U.S. Cl. CPC H05K 1/0228; H05K 1/025; H05K 2201/09227; H05K 2201/09727

(57) ABSTRACT

Provided is a high-speed transmission board wiring structure capable of suppressing crosstalk to an adjacent wiring pattern and reducing insertion loss and return loss. A high-speed transmission board wiring structure that connects a plurality of ICs includes: a first transmission line P1 that has a characteristic impedance lower than an impedance of the ICs (M1 and M1a) and transmits a signal; and second transmission lines P2, P2a, and P12 each of which has a line width smaller than a line width of the first transmission line P1, connects one of the ICs (M1 and M1a) and the first transmission line P1, and transmits the signal. Each of the second transmission lines P2, P2a, and P12 has a line length of n/4 of a wavelength λ of the signal to be transmitted, where n is an integer of 1 or more.

### TECHNICAL FIELD

The present invention relates to the structure of a board wiring for propagating a high-speed signal.

### BACKGROUND ART

A plurality of wiring patterns are formed on a board wiring provided in an electronic device, and arrangement of the wiring patterns tends to increase in density with miniaturization of devices. In addition, as the signal transmission rate increases, high-speed signals flow through the wiring patterns, and crosstalk between adjacent wirings increases.

Therefore, it is necessary to suppress crosstalk.

In addition to suppression of crosstalk, it is also important for the wiring patterns to reduce insertion loss in wiring design in order to improve the degree of freedom in layout of an IC or a connector to be connected on the board.

PTL 1 discloses a board wiring that suppresses crosstalk. In this board wiring, in a portion where a plurality of wiring patterns are arranged, parts where adjacent wiring patterns are close to each other and parts where the adjacent wiring patterns are separated from each other are alternately arranged by the wirings being bent, so that crosstalk is reduced.

### CITATION LIST

### Patent Literature

PTL 1: JP 2017-135142 A

### SUMMARY OF INVENTION

### Technical Problem

To improve processing capability in the future, further high-speed communication is required. In high-speed communication, not only reduction of crosstalk but also reduction of insertion loss and return loss is required.

However, when wiring patterns are formed by the technique described in PTL 1, an effect of reducing insertion loss and return loss cannot be expected although crosstalk between adjacent wiring patterns can be suppressed.

An object of the present invention is to provide a high-speed transmission board wiring structure capable of suppressing crosstalk to an adjacent wiring pattern and reducing insertion loss and return loss.

### Solution to Problem

In order to achieve the above object, the present invention is configured as follows.

A high-speed transmission board wiring structure that connects a plurality of ICs includes: a first transmission line that has a characteristic impedance lower than an impedance of the ICs and transmits a signal; and second transmission lines each of which has a line width smaller than a line width of the first transmission line, connects one of the ICs and the first transmission line, and transmits the signal, wherein each of the second transmission lines has a line length of n/4 of a wavelength λ of the signal, where n is an integer of 1 or more.

### Advantageous Effects of Invention

According to the present invention, it is possible to provide a high-speed transmission board wiring structure capable of suppressing crosstalk to an adjacent wiring pattern and reducing insertion loss and return loss.

### BRIEF DESCRIPTION OF DRAWINGS

FIG. 1 is a plan view of a wiring pattern 1 according to a first embodiment of the present invention.

FIG. 2 is an explanatory diagram of a A/4 transformer.

FIG. 3 is a diagram illustrating an example of specific dimensions of the wiring pattern 1 illustrated in FIG. 1.

FIG. 4 is a plan view in a case where ICs are connected by the wiring pattern 1 of the first embodiment of the present invention.

FIG. 5 is a plan view illustrating a wiring pattern different from that of the present invention.

FIG. 6 is a plan view in a case where ICs are connected by a wiring pattern 2 different from that of the present invention.

FIG. 7 is a plan view illustrating a wiring pattern according to a second embodiment of the present invention.

FIG. 8A is a cross-sectional view of a crosstalk noise analysis model in the second embodiment of the present invention.

FIG. 8B is a cross-sectional view of a crosstalk noise analysis model in an example different from the present invention.

FIG. 8C is a cross-sectional view of a crosstalk noise analysis model in another example different from the present invention.

FIG. 9 is a diagram illustrating crosstalk noise analysis results.

FIG. 10 is a graph illustrating analytical values of frequency characteristics of insertion loss in wiring patterns of the second embodiment of the present invention and the another example different from the present invention.

FIG. 11 is an analytical value graph of frequency characteristics of insertion loss in the wiring patterns of the second embodiment of the present invention in which a line length is extended and the another example different from the present invention.

FIG. 12 is a schematic configuration diagram of a third embodiment of the present invention.

### DESCRIPTION OF EMBODIMENTS

Hereinafter, embodiments of a high-speed transmission board wiring according to the present invention will be described with reference to the drawings.

### EMBODIMENTS

### First Embodiment

FIG. 1 is a plan view of a wiring pattern 1 (high-speed transmission board wiring structure) according to a first embodiment of the present invention.

The wiring pattern 1 is formed on a rigid board or flexible board 1k, and the wiring pattern 1 is formed of a conductive metal layer such as a copper foil. The wiring pattern 1 is a conductor that connects a transmission side IC and a reception side IC or connects an IC and a connector, and includes a first transmission line P1 that transmits a signal and a second transmission line P2 that transmits a signal.

The first transmission line P1 has a line width W1. The second transmission line P2 includes portions of a first thin line portion P2-1 connected to the first transmission line P1 and having a line width W21 and a line length L21 and a second thin line portion P2-2 connected to the first thin line portion P2-1 and having a line width W22 and a line length L22, and is connected to an IC or a connector.

In addition, the lengths L21 and L22 of the portions of the line widths W21 and W22 forming the second transmission line P2 each have a wiring line length of ¼ of a wavelength λ of a signal frequency. The line width W21 of the first thin line portion P2-1 and the line width W22 of the second thin line portion P2-2 are different, and the line width W22 is smaller than the line width W21.

For the purpose of reducing insertion loss, the line width W1 of the first transmission line P1 is set to have a characteristic impedance lower than the impedance of the IC or the connector to be connected.

The line widths W21 and W22 of the second transmission line P2 are smaller than the line width W1 of the first transmission line P1, and each have a characteristic impedance higher than the characteristic impedance of the transmission line P1 and higher than the impedance of the IC to be connected.

Here, the line width W1 of the first transmission line P1 and the line widths W21 and W22 of the second transmission line P2 are formed to have impedances calculated by a generally known λ/4 transformer calculation formula.

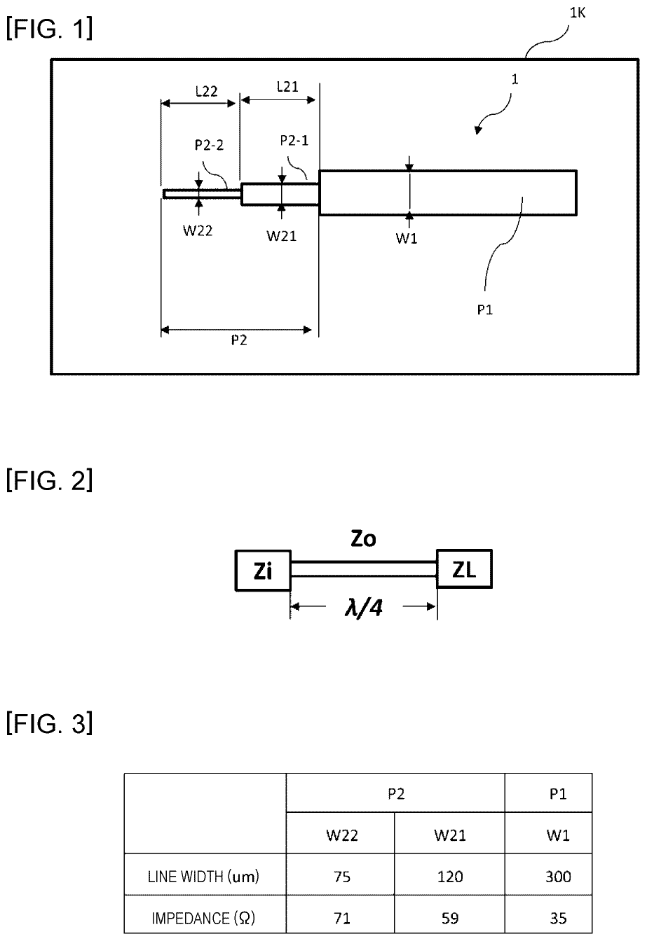

FIG. 2 is an explanatory diagram of a λ/4 transformer calculation formula.

As illustrated in FIG. 2, when two different impedances Zᵢ and Z_{L} are connected by a line having a length of ¼ of the wavelength λ of a signal frequency f and an impedance Z₀ satisfying the following formulas (1) and (2), the impedances are matched at the frequency f, and return loss is suppressed.

$${Z}_{i} = {Z}_{0}^{2} / {Z}_{L} \qquad ( 1 )$$

$${Z}_{0} = √ ( {Z}_{i} \cdot {Z}_{L} ) \qquad ( 2 )$$

In addition, in the λ/4 transformer, the impedances are matched not only at the signal frequency f but also at harmonic frequencies of odd multiples, such as 3f, 5f, and 7f, and the reflected wave is suppressed, which makes it possible to transmit even a rectangular wave signal without deteriorating the waveform.

Determining the line widths of the second transmission line P2 so as to satisfy the λ/4 transformer calculation formula makes it possible to maintain impedance matching and make the line widths of the second transmission line P2 smaller than that of the first transmission line P1.

Here, the line length of the second transmission line P2 can be n/4 of the wavelength λ, where n is an integer of 1 or more.

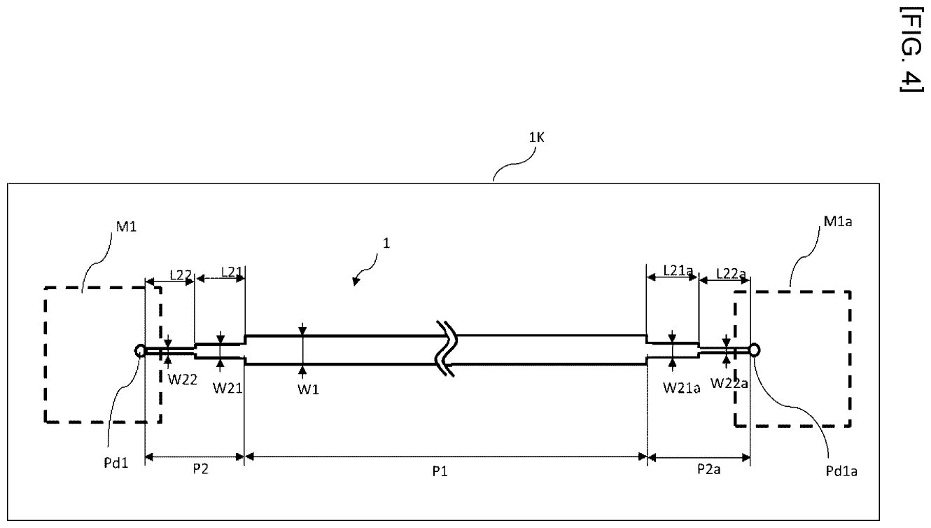

FIG. 3 illustrates an example of specific dimensions of the wiring pattern 1 illustrated in FIG. 1 in a case where a microstrip line satisfying an impedance of 50Ω is designed on an FR4 board having an insulating layer thickness of 100 um.

As illustrated in FIG. 3, the line width W1 of the first transmission line P1 is 300 um and has an impedance of 35Ω, which is lower than the general impedance 50Ω of the IC to be connected.

The line width W21 of the second transmission line P2 is 120 um and has an impedance of 59Ω, and the line width W22 is 75 um and has an impedance of 71Ω.

In addition, the lengths L21 and L22 of the portions of the line widths W21 and W22 forming the second transmission line P2 are wiring line lengths of ¼ of the wavelength λ of the signal frequency, and are generally known to be, for example, 3.6 mm when the signal frequency is 10 GHZ and 1.8 mm when the signal frequency is 20 GHZ.

FIG. 4 is a plan view in a case where an IC (M1) and an IC (M1a) are connected by the wiring pattern 1 of the first embodiment of the present invention. Furthermore, in FIG. 4, both M1 and M1a are denoted as ICs, but can also be implemented by connectors.

A pad Pd1 of the IC (M1) on one end side is connected to the first transmission line P1 by the second transmission line P2, and a pad Pd1a of the IC (M1a) on the other end side is connected to the first transmission line P1 by a second transmission line P2a. The second transmission line includes two transmission lines P2 and P2a. Similarly to the transmission line P2, the second transmission line P2a also includes a first thin line portion P2-1 and a first thin line portion P2-2, and the line lengths and line widths of these portions are configured similarly to those of the second transmission line P2.

The line lengths L21 and L22 of the second transmission line P2 on the IC (M1) side and line lengths L21a and L22a of the second transmission line P2a on the IC (M1a) side are as long as the wiring line of the first embodiment having ¼ of the wavelength λ of the signal frequency.

As long as the λ/4 transformer formula (1) is satisfied, the line width W21 of the second transmission line P2 on the IC (M1) side and a line width W21a of the second transmission line P2a on the IC (M1a) side do not have to be the same width, and can be implemented by different line widths, and the same applies to the line width W22 and a line width W22a.

In the wiring pattern 1 of the first embodiment of the present invention illustrated in FIG. 4, the impedances at the signal frequency are matched between the pad Pd1 of the IC (M1) and the pad Pd1a of the IC (M1a), and thus it is possible to suppress return loss.

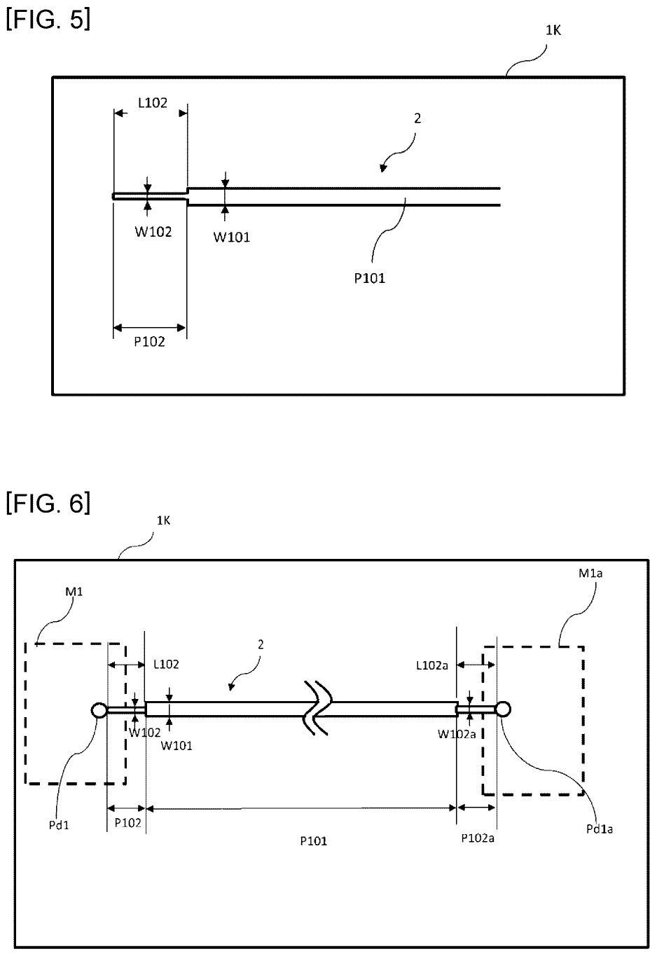

FIG. 5 is a plan view illustrating a wiring pattern 2 different from that of the present invention, and FIG. 6 is a plan view in a case where ICs are connected by the wiring pattern 2 different from that of the present invention.

The line widths W22 and 22a of the second transmission lines P2 and P2a in the wiring pattern 1 of the first embodiment of the present invention illustrated in FIGS. 1 and 4 can be made smaller than a line width W101 of a first transmission line P101 of the wiring pattern 2 illustrated in FIG. 6 in a state where impedance matching is maintained at the signal frequency f.

In the wiring pattern 1 of the first embodiment of the present invention illustrated in FIGS. 1 and 4, due to the characteristics of the λ/4 transformer, the impedances are matched not only at the signal frequency f but also at harmonic frequencies of odd multiples, such as 3f, 5f, and 7f, and return loss is suppressed, which makes it possible to transmit a rectangular wave signal without deteriorating the waveform.

In the wiring pattern 1 of the first embodiment of the present invention illustrated in FIGS. 1 and 4, the impedance of the first transmission line P1 is lower than the impedance of the IC to be connected, and the line width W1 is larger than the line width W101 of the first transmission line P101 of the wiring pattern 2 illustrated in FIGS. 5 and 6.

Since the line width W1 is larger than the line width W101, the coupling capacitance with a ground layer increases, and the radiation amount of the signal power decreases, which makes it possible to suppress crosstalk.

In addition, since the line width W1 is larger than the line width W101, the series resistance of the conductive metal layer, such as a copper foil, forming the wiring pattern is reduced, and it is possible to reduce insertion loss.

Here, the wiring pattern 2 illustrated in FIG. 5, which is an example different from the present invention, will be supplemented.

The wiring pattern 2 illustrated in FIG. 5 includes the first transmission line P101 and a second transmission line P102. The first transmission line P101 has the line width W101, and the second transmission line P102 has a line width W102 and is connected to an IC at a line length L102.

The line width W101 of the first transmission line P101 has an impedance equal to the impedance of the IC to be connected.

The line width W102 of the second transmission line P102 is smaller than the line width W101 of the first transmission line P101, and is defined by layout conditions such as the position of the pad of the IC to be connected and the interval between the pads.

The line length L102 of the second transmission line P102 is defined by the layout conditions such as the position of the pad of the IC to be connected and the interval between the pads.

In the example illustrated in FIG. 6, which is different from the present invention, the IC (M1) and the IC (M1a) are connected by the wiring pattern 2.

The pad Pd1 of the IC (M1) is connected to the first transmission line P101 by the second transmission line P102, and the pad Pd1a of the IC (M1a) is connected to the first transmission line P101 by a second transmission line P102a.

In the first transmission line P101, the line width W101 is selected so as to have the same impedance as the impedance of the IC (M1) and the IC (M1a), but the second transmission line P102 having the line width W102 or a line width W102a smaller than the line width W101 is required depending on the layout condition such as the pad positions of the IC (M1) and the IC (M1a) or the interval between the pads.

Since the line widths W102 and W102a are smaller than the line width W101 and have high impedances, a return loss occurs due to impedance mismatch.

In the wiring structure illustrated in FIG. 6, which is different from that of the present invention, it is difficult to implement reduction of insertion loss and suppression of return loss as in the first embodiment of the present invention.

The first embodiment of the present invention reduces return loss that may occur due to the characteristic impedance discontinuity of a wiring pattern when reducing insertion loss, and controls the characteristic impedances of the wiring pattern, so that it is possible to simultaneously reduce the return loss.

That is, according to the first embodiment of the present invention, it is possible to provide a high-speed transmission board wiring structure capable of suppressing crosstalk to an adjacent wiring pattern and reducing insertion loss and return loss.

The line widths of the second transmission lines P2 and

P2a are set such that the second transmission lines P2 and P2a have characteristic impedances in which no mismatch occurs according to the amount of change in characteristic impedance at both ends.

### Second Embodiment

Next, a second embodiment of the present invention will be described.

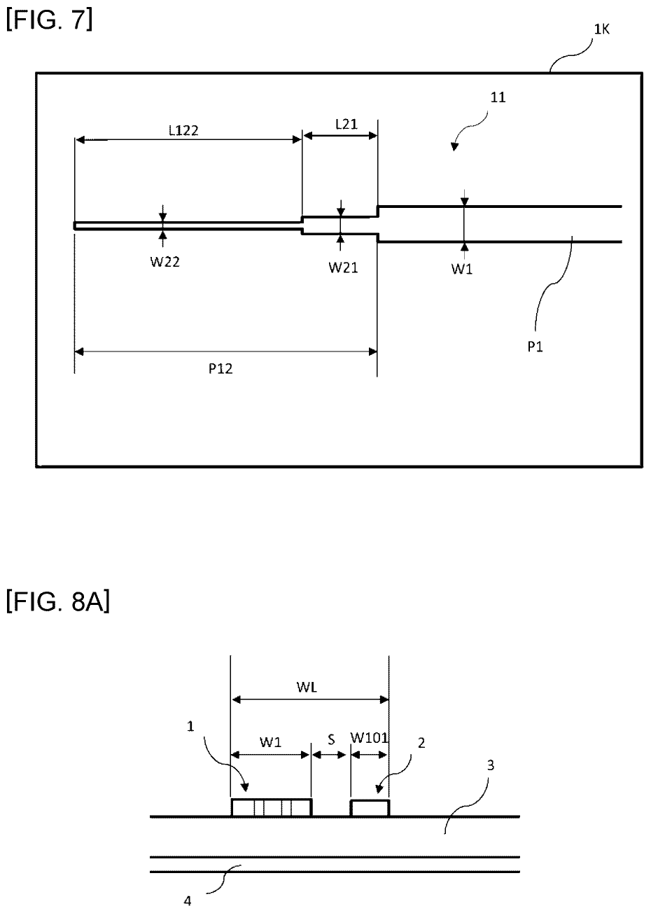

FIG. 7 is a plan view of a wiring pattern 11 (high-speed transmission board wiring structure) according to the second embodiment of the present invention.

n FIG. 7, the wiring pattern 11 includes a first transmission line P1 and a second transmission line P12. The first transmission line P1 has a line width W1, and the second transmission line P12 includes a portion having a line width W21 and a line length L21 and a portion having a line width W22 and a line length L122, and is connected to an IC or a connector.

In the portion of the second transmission line P12 having the line width W22 and the line length L122, the line length L122 is set to a length that is an odd multiple of λ/4 in a case where the wavelength of a signal frequency f is λ.

Since the line length L122 is set to a length that is an odd multiple of λ/4 of the signal frequency f, impedance matching can be maintained at the signal frequency f and the harmonic frequencies 3f, 5f, 7f, and the like that are odd multiples of the signal frequency f, similarly to the wiring pattern 1 of the first embodiment of the present invention.

As long as the line length L122 is an odd multiple of λ/4 of the signal frequency f, the length of the line length L122 can be freely selected, and even in a case where layout conditions, such as the position of the pad of the IC or the connector to be connected and the interval between the pads, are severe, it is possible to form a line while maintaining impedance matching at the signal frequency f and the harmonic frequencies 3f, 5f, 7f, and the like that are odd multiples of the signal frequency f.

Also in the second embodiment, similarly to the first embodiment illustrated in FIG. 4, a first transmission line and second transmission lines (connected to both ends of the first transmission line) are provided, and the configuration of the second transmission line P12 is only different from that of the first embodiment. Therefore, a plan view in a case where ICs are connected by the wiring pattern 11 of the second embodiment is omitted.

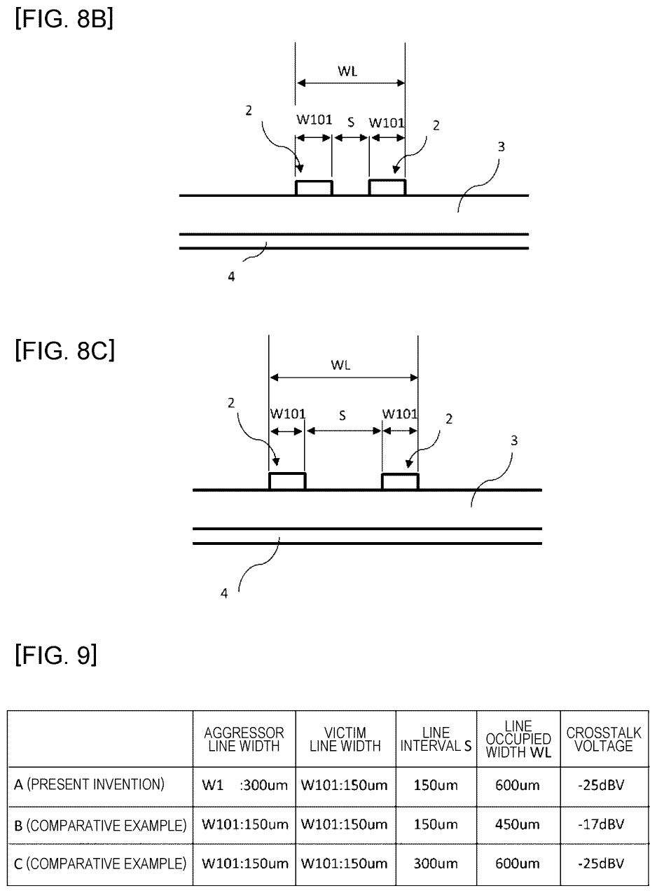

FIG. 8A is a cross-sectional view of a wiring pattern 1 of the second embodiment of the present invention as an aggressor line on a side that generates crosstalk noise, FIG. 8B is a cross-sectional view of a wiring pattern 2 in an example (comparative example) different from the present invention, and FIG. 8C is a cross-sectional view of the line pattern 2 in another example (comparative example) different from the present invention.

In FIG. 8A, the wiring pattern 1 and the wiring pattern 2 formed of copper having a thickness of 35 um are disposed on the upper surface of a dielectric board 3 having a relative permittivity of 4, a dielectric loss tangent of 0.005, a layer thickness of 100 um, and a length of 10 cm, which are general in an FR4 board. In FIGS. 8B and 8C, the wiring patterns 2 are arranged, and the lower surface of the dielectric board 3 is entirely covered with a ground layer 4 formed of copper having a thickness of 35 um.

In FIG. 8A, the wiring pattern 1 of the second embodiment of the present invention in which the line width W1 of the first transmission line P1 is 300 um is set as an aggressor line, and the wiring pattern 2, which is a victim line, is arranged with a line interval S of 150 um. A line width W101 of a first transmission line P101 is 150 um.

At this time, a width (line occupied width) WL occupied by the pair of lines, which is obtained by summing up the aggressor line width W1, the victim line width W101, and the line interval S, is 600 um.

In FIG. 8B, the wiring pattern 2 in which the line width W101 of the first transmission line P101 is 150 um is set as an aggressor line, a line interval S of 150 um is provided, and the wiring pattern 2 in which the line width W101 of the first transmission line P101 is also 150 um is set as a victim line and arranged in parallel with the aggressor line.

At this time, the width WL occupied by the pair of lines, which is obtained by summing up the aggressor line width W101, the victim line width W101, and the line interval S, is 450 um.

In FIG. 8C, the wiring pattern 2 in which the line width W101 of the first transmission line P101 is 150 um is set as an aggressor line, a line interval S of 300 um is provided, and the wiring pattern 2 in which the line width W101 of the first transmission line P101 is also 150 um is set as a victim line and arranged in parallel with the aggressor line.

At this time, the width WL occupied by the pair of lines, which is obtained by summing up the aggressor line width, the victim line width, and the line interval, is 600 um.

FIG. 9 is a diagram illustrating analytical values of the crosstalk voltage observed at the victim line when a signal having a frequency of 10 GHZ and an amplitude voltage of 1 V is input to the aggressor line in FIGS. 8A, 8B, and 8C.

When A (the present invention) and B (the example illustrated in FIG. 8B), in which the line interval S has the same value of 150 um, are compared in FIG. 9, it can be seen that, in the case where the aggressor line is the wiring pattern 1 of the present invention, the crosstalk decreases by 8 dBV, from −17 dBV to −25 dBV, as compared with the case where the aggressor line is the wiring pattern 2.

In addition, when A and C (the example illustrated in FIG. 8C) are compared in FIG. 9, it can be seen that, in the case where the width WL occupied by the pair of lines, which is obtained by summing up the aggressor line width W1, the victim line width W101, and the line interval S, has the same value of 600 um, the crosstalk voltage is −25 dBV, which is equal between A and C.

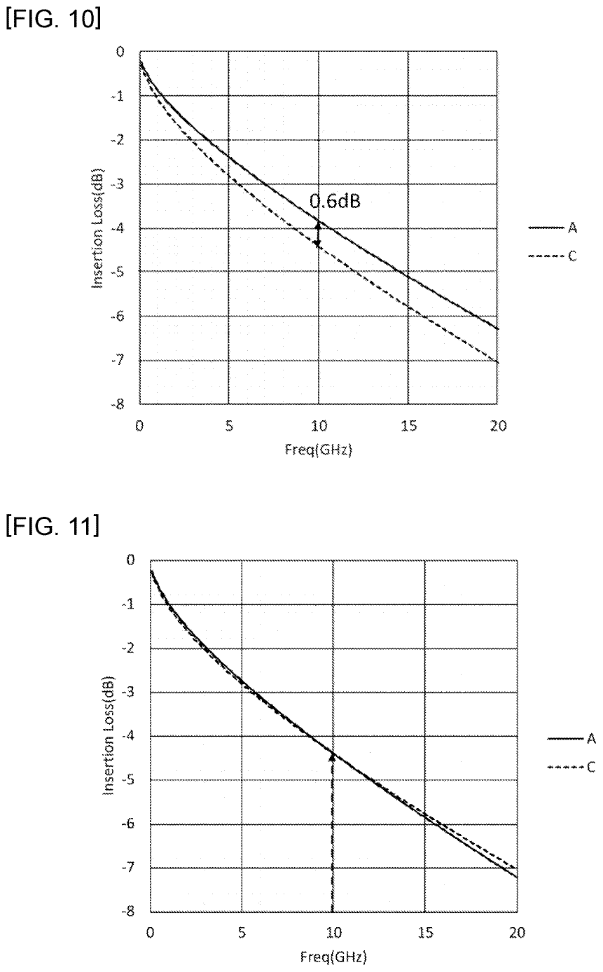

FIG. 10 is a graph illustrating analytical values of frequency characteristics of insertion loss of the first transmission line P1 of the wiring pattern 1 of the second embodiment of the present invention, which is the aggressor line in FIG. 8A, and the first transmission line P101 of the wiring pattern 2, which is the aggressor line in FIG. 8C.

The line width W1 of the transmission line P1 is 300 um, the line width W101 of the transmission line P101 is 150 um, and the line length of each of the transmission lines P1 and P101 is 20 cm.

For example, comparing the insertion loss at 10 GHz, it can be seen that the wiring pattern 1 of the second embodiment of the present invention has a loss smaller than that of the wiring pattern 2 by 0.6 dB.

FIG. 11 is a graph illustrating frequency characteristics of insertion loss in a case where the length of the first transmission line P1 of the wiring pattern 1 of the second embodiment of the present invention is adjusted such that the insertion loss of the first transmission line P101 of the wiring pattern 2 and the insertion loss of the wiring pattern 1 are equal at 10 GHz in FIG. 10.

As illustrated in FIG. 11, with respect to the length 20 cm of the first transmission line P101 of the wiring pattern 2 having a line width of 150 um, the insertion loss at 10 GHz is equal when the length of the first transmission line P1 of the wiring pattern 1 of the second embodiment of the present invention having a line width of 300 um is set to 23 cm.

Setting the line width from 150 um to 300 um makes it possible to reduce the insertion loss and extend the wiring line length P1 by 15%.

As described above, according to the wiring structure of the second embodiment of the present invention, it is possible to suppress crosstalk, reduce return loss and insertion loss, and further extend the wiring, which makes it possible to obtain an effect that the degree of freedom in designing a wiring layout can be improved.

### Third Embodiment

Next, a third embodiment of the present invention will be described.

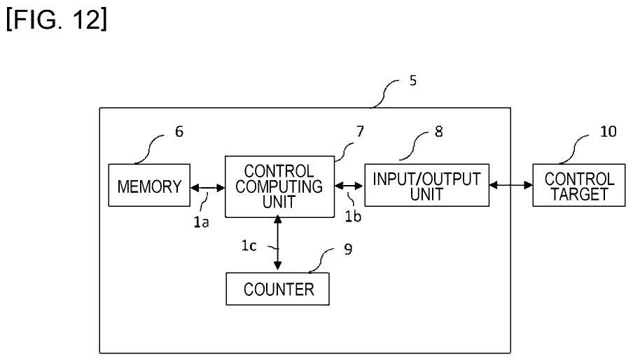

FIG. 12 is a schematic configuration diagram of the third embodiment. In FIG. 12, an electronic control device 5 includes a memory 6, a control computing unit 7, an input/output unit 8, and a counter 9. The control computing unit 7 executes control computation for controlling a control target 10 using the memory 6 and the counter, and controls the operation of the control target 10 via the input/output unit 8. The memory 6, the control computing unit 7, the input/output unit 8, and the counter 9 are ICs.

The memory 6 and the control computing unit 7 are connected by a wiring pattern 1a, and the control computing unit 7 and the input/output unit 8 are connected by a wiring pattern 1b. In addition, the control computing unit 7 and the counter 9 are connected by a wiring pattern 1c.

The wiring patterns 1a, 1b, and 1c are wiring patterns each having a configuration similar to the wiring pattern 1 of the first embodiment or the wiring pattern 11 of the second embodiment. That is, the plurality of ICs in the electronic control device 5 are connected by the first transmission line P1 and the second transmission lines P2 and P12.

According to the third embodiment of the present invention, it is possible to provide the electronic control device 5 including the plurality of ICs connected by the high-speed transmission board wiring structure capable o suppressing crosstalk to an adjacent wiring pattern and reducing insertion loss and return loss.

Note that the counter 9 of the electronic control device 5 is not necessarily required, and may be omitted.

Although the embodiments of the present invention have been described above, the present invention is not limited to the above-described embodiments, and various modifications can be made without departing from the spirit of the invention described in the claims.

### REFERENCE SIGNS LIST

1, 1a, 1b, 1c, 2, 11 wiring pattern
3 dielectric board
4 ground layer
5 electronic control device
6 memory
7 control computing unit
8 input/output unit
9 counter
10 control target
1 k rigid board or flexible board
P1, P101, P101a first transmission line
P2, P2a, P12, P102, P102a second transmission line
P2-1 first thin line portion
P2-2 second thin line portion
W1, W21, W22, W21a, W22a, W101, W102, W102a line width
L21, L22, L21a, L22a, L102, L102a, L122 line length
Z₀, Zᵢ, Z_{L} impedance
M1, M1a IC
Pd1, Pd1a pad
S line interval
WL line occupied width

1. A high-speed transmission board wiring structure that connects a plurality of ICs, the high-speed transmission board wiring structure comprising:
a first transmission line that has a characteristic impedance lower than an impedance of the ICs and transmits a signal; and
second transmission lines each of which has a line width smaller than a line width of the first transmission line, connects one of the ICs and the first transmission line, and transmits the signal,
wherein
each of the second transmission lines has a line length of n/4 of a wavelength λ of the signal, where n is an integer of 1 or more.

2. The high-speed transmission board wiring structure according to claim 1, wherein
the line length of each of the second transmission lines is an odd multiple of ¼ of the wavelength λ.

3. The high-speed transmission board wiring structure according to claim 2, wherein
each of the second transmission lines includes a plurality of thin line portions having different line widths.

4. The high-speed transmission board wiring structure according to claim 3, wherein
the line width of each of the second transmission lines decreases from the first transmission line toward one of the ICs.

5. The high-speed transmission board wiring structure according to claim 2, wherein
each of the second transmission lines has a characteristic impedance higher than the impedance of the ICs.

6. The high-speed transmission board wiring structure according to claim 2, wherein
the line width of each of the second transmission lines is a width having a characteristic impedance matching according to a characteristic impedance of the ICs.

7. The high-speed transmission board wiring structure according to claim 5, wherein
the characteristic impedance of each of the second transmission lines is calculated by a λ/4 transformer calculation formula.

8. The high-speed transmission board wiring structure according to claim 1, wherein
the plurality of ICs in an electronic control device are connected.
